(19) United States
(12) Patent Application Publication
(10) Pub. No.: US 2026/0231553 A1
(43) Pub. Date: Aug. 6, 2026

(54) IMAGE SENSING DEVICE AND METHOD FOR MANUFACTURING THE SAME

(71) Applicant: SK hynix Inc., Icheon-si (KR)

(72) Inventor: Ji Suk PARK, Icheon-si (KR)

(21) Appl. No.: 19/255,810

(22) Filed: Jun. 30, 2025

(30) Foreign Application Priority Data
Feb. 3, 2025 (KR) 10-2025-0013131

(51) Int. Cl. H10F 39/00

(52) U.S. Cl. CPC H10F 39/812; H10F 39/024; H10F 39/80373; H10F 39/805

(57) ABSTRACT

An image sensing device and a method for manufacturing the same are disclosed. The image sensing device includes a semiconductor substrate; a well region in the semiconductor substrate and including first-type impurities; a photoelectric conversion region disposed below the well region to be in contact with the well region and including second-type impurities opposite to the first-type impurities; a transfer gate including a recess gate embedded in the semiconductor substrate; and a first passivation layer disposed to cover at least one side surface and a bottom surface of the recess gate within the semiconductor substrate. A portion of the photoelectric conversion region is in contact with the side surface of the recess gate.

### CROSS-REFERENCE TO RELATED APPLICATION

This patent document claims the priority and benefits of Korean patent application No. 10-2025-013131, filed on Feb. 3, 2025, which is incorporated by reference in its entirety as part of the disclosure of this patent document.

### TECHNICAL FIELD

The technology and implementations disclosed in this patent document generally relate to an image sensing device and a method for manufacturing the same.

### BACKGROUND

An image sensor is a device for capturing optical images by converting light into electrical signals using a photosensitive semiconductor material which reacts to light. With the recent development of automotive, medical, computer and communication industries, the demand for high-performance image sensors is increasing in various fields such as smartphones, digital cameras, camcorders, personal communication systems (PCSs), game consoles, IoT (Internet of Things), robots, surveillance cameras, medical micro cameras, etc.

### SUMMARY

Various embodiments of the disclosed technology relate to an image sensing device with improved operation characteristics.

In accordance with an embodiment of the disclosed technology, an image sensing device may include a semiconductor substrate; a well region in the semiconductor substrate and including first-type impurities; a photoelectric conversion region disposed below the well region to be in contact with the well region and including second-type impurities opposite to the first-type impurities, the photoelectric conversion region configured to generate photocharges in response to light incident on the photoelectric conversion region; a transfer gate including a recess gate embedded in the semiconductor substrate and configured to transfer the photocharges; and a first passivation layer disposed to cover at least one side surface and a bottom surface of the recess gate within the semiconductor substrate, wherein a portion of the photoelectric conversion region is in contact with the side surface of the recess gate.

In accordance with another embodiment of the disclosed technology, an image sensing device may include a plurality of unit pixels disposed adjacent to each other; and a floating diffusion region disposed between the plurality of unit pixels and shared by the plurality of unit pixels to receive photocharge from the plurality of unit pixels. Each of the plurality of unit pixels may include: a semiconductor substrate; a photoelectric conversion region disposed in the semiconductor substrate that converts incident light into photocharge; a well region disposed on the photoelectric conversion region and being in contact with the photoelectric conversion region within the semiconductor substrate; a recess gate disposed in the semiconductor substrate and having a first side surface being in contact with the photoelectric conversion region and a second side surface opposite to the first side surface; and a first passivation layer covering the second side surface and a bottom surface of the recess gate within the semiconductor substrate.

In accordance with another embodiment of the disclosed technology, a method for manufacturing an image sensing device may include forming a first photoelectric conversion region in a semiconductor substrate including impurities of a first type by implanting impurities of a second type opposite to the first type; forming a trench by etching the semiconductor substrate; forming a passivation layer on sidewalls and a bottom surface of the trench by implanting the first-type impurities into the trench; forming a mask pattern covering a portion of the trench over the semiconductor substrate; forming a second photoelectric conversion region contacting a portion of side surfaces of the trench by implanting the second-type impurities into the semiconductor substrate using the mask pattern as an ion implantation mask; and forming a transfer gate to fill the trench.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2 is a plan view illustrating an example of a planar structure of one pixel block in a pixel array shown in FIG. 1 based on some embodiments of the disclosed technology.

FIG. 3 is a cross-sectional view illustrating a cross-section of the pixel block taken along the line A-A′ shown in FIG. 2 based on some embodiments of the disclosed technology.

FIG. 4 is a cross-sectional view illustrating a cross-section of the pixel block taken along the line B-B′ shown in FIG. 2 based on some embodiments of the disclosed technology.

FIGS. 5A, 6A, 7A, 8A and 9A are cross-sectional views illustrating example methods of forming the structure shown in FIG. 3 based on some embodiments of the disclosed technology.

FIGS. 5B, 6B, 7B, 8B and 9B are cross-sectional views illustrating example methods of forming the structure shown in FIG. 4 based on some embodiments of the disclosed technology.

FIG. 10 is a plan view illustrating an example of a mask pattern for forming a second photoelectric conversion region based on some embodiments of the disclosed technology.

### DETAILED DESCRIPTION

This patent document provides implementations and examples of an image sensing device and a method for manufacturing the same that may be used to substantially address one or more technical or engineering issues and mitigate limitations or disadvantages encountered in some other image sensing devices. The disclosed technology can be implemented in some embodiments to provide an imagen sensing device that can improve its operational characteristics. The disclosed technology can be implemented in some embodiments to provide an image sensing device with improved operation characteristics. The disclosed technology can be implemented in some embodiments to provide an image sensing device that can increase transmission efficiency of a transfer transistor. The disclosed technology can be implemented in some embodiments to provide an image sensing device that can reduce the degree of influence caused by dark sources.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

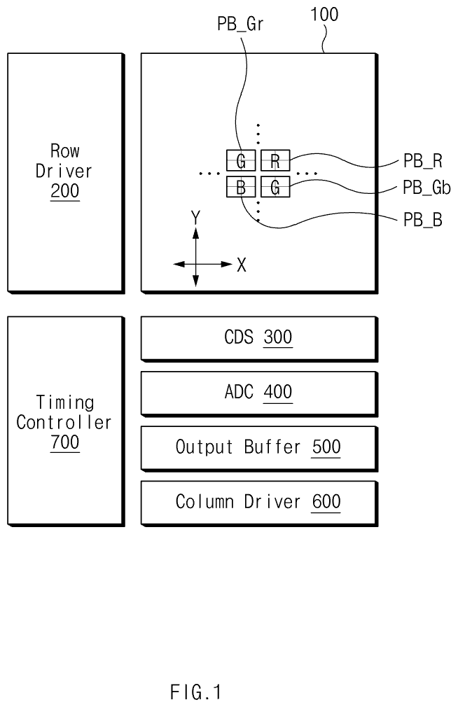

FIG. 1 is a block diagram illustrating an example of an image sensing device according to embodiments of the disclosed technology.

Referring to FIG. 1, the image sensing device may include a pixel region 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of pixel blocks (PB_R, PB_Gr, PB_Gb, PB_B) consecutively arranged in a two-dimensional (2D) matrix including rows and columns. The pixel blocks (PB_R, PB_Gr, PB_Gb, PB_B) may be arranged in a Bayer pattern. Each of the pixel blocks (PB_R, PB_Gr, PB_Gb, PB_B) may include a structure in which a plurality of unit pixels shares one floating diffusion region. Each unit pixel may include a photoelectric conversion region (e.g., a photodiode PD) that generates photocharges through photoelectric conversion of incident light, and at least one transfer gate that transmits the photocharges generated by the photoelectric conversion region to a floating diffusion region in response to a transfer signal. The transfer gate may include a recess gate embedded in the semiconductor substrate. Adjacent unit pixels may be isolated from each other by a trench-type pixel isolation structure.

The row driver 200 may operate the unit pixels based on control signals received from a control circuit such as the timing controller 700. The row driver 200 may select at least one unit pixel connected to at least one row line of the pixel array 100.

The correlated double sampler (CDS) 300 may remove undesired offset values of the unit pixels using correlated double sampling.

The ADC 400 may convert the CDS signal received from the correlated double sampler (CDS) 300 into a digital signal.

The output buffer 500 may temporarily store column-based data received from the ADC 400 under the control of the timing controller 700.

The column driver 600 may select a column of the output buffer 500 under the control of the timing controller 700, and may sequentially output data temporarily stored in the selected column of the output buffer 500.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

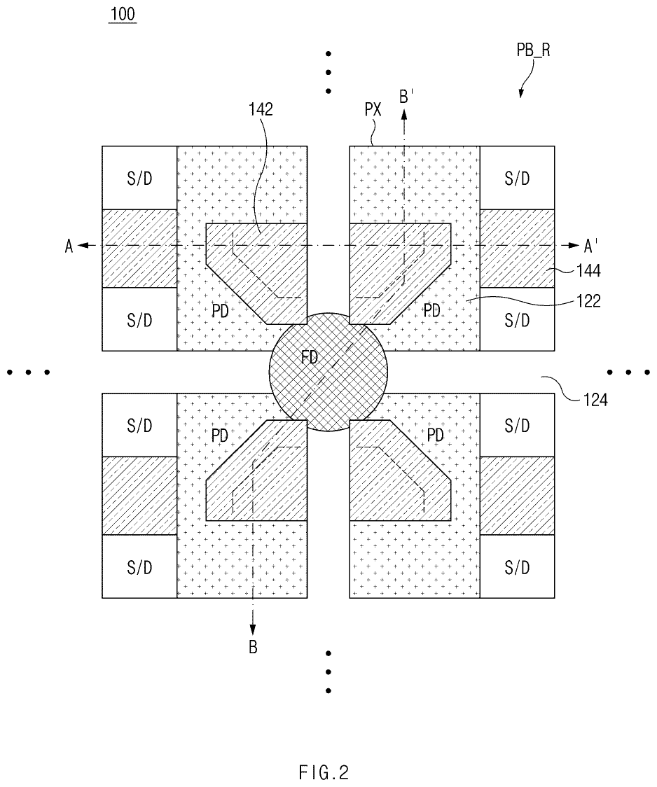

FIG. 2 is a plan view illustrating an example of a planar structure of one pixel block in the pixel array 100 shown in FIG. 1 based on some embodiments of the disclosed technology.

In the example as shown in FIG. 2, the pixel block (PB_R) is mainly described as the representative example. Since the pixel blocks (PB_R, PB_Gr, PB_Gb, PB_B) have the same structure except for the color of the color filter, the description provided for the pixel block (PB_R) can be applied to other pixels in the pixel block.

Referring to FIG. 2, the pixel block (PB_R) may include four unit pixels (PXs) adjacently arranged in a (2×2) matrix structure. In the example, the four unit pixels (PXs) may share one floating diffusion region (FD). For example, only one floating diffusion region (FD) that stores photocharges generated by the unit pixels (PXs) may be formed in a central portion of the pixel block (PB_R) and shared by the unit pixels (PXs) of the pixel block (PB_R).

Each unit pixel (PX) may include two pixel transistors. For example, each unit pixel (PX) may include a transfer transistor and a drive transistor.

The transfer transistor may transfer photocharges generated by the photoelectric conversion region of the corresponding unit pixel (PX) to the floating diffusion region (FD) based on a transfer signal from the row driver 200. The transfer transistor may be a transistor having the photoelectric conversion region (PD) and the floating diffusion region (FD) as source/drain regions. A gate (e.g., a transfer gate) 142 of the transfer transistor may include a recess gate, at least a portion of which is embedded in the semiconductor substrate to form a channel in a vertical direction. In the present embodiment, the transfer gate 142 may refer to a structure including a gate electrode and a gate insulation layer. The gate insulation layer may be formed between the gate electrode and the semiconductor substrate.

The drive transistor may be isolated from the transfer gate 142 by a device isolation structure 122, and may include a drive gate 144 and source/drain regions (S/D) located at both sides of the drive gate 144. In the present embodiment, the drive gate 144 may refer to a structure including a gate electrode and a gate insulation layer. The gate insulation layer may be formed between the gate electrode and the semiconductor substrate.

Each drive transistor may operate as one of a reset transistor configured to initialize the floating diffusion region (FD) in response to a reset signal, a source follower transistor configured to generate a pixel signal corresponding to the magnitude of photocharges stored in the floating diffusion region (FD), a selection transistor configured to output the pixel signal output from the source follower transistor to a column line in response to a row selection signal, or a conversion gain transistor configured to adjust capacitance of the floating diffusion node (FD). For example, four drive transistors of the pixel block (PB_R) may be connected to each other through a conductive line or may be connected to the floating diffusion region (FD) to be shared by the four unit pixels (PXs), so that the four drive transistors operate as any one of a reset transistor, a source follower transistor, a selection transistor, or a conversion gain transistor.

Adjacent unit pixels (PXs) may be isolated from each other by a pixel isolation structure 124, and the transfer gate 142 and the drive transistor within each unit pixel (PX) may be isolated from each other by the device isolation structure 122. Each of the device isolation structure 122 and the pixel isolation structure 124 may include a trench-type isolation structure in which an insulation material is embedded in an etched region obtained by etching the substrate. For example, the device isolation structure 122 may include a shallow trench isolation (STI) structure, and the pixel isolation structure 124 may include a deep trench isolation (DTI) structure.

The transfer gates 142 and the drive transistors may be arranged symmetrical to each other between adjacent unit pixels (PXs) within the pixel block (PB_R). For example, the transfer gates 142 of the two unit pixels that are adjacent to each other along a row direction or a column direction are arranged symmetrical to each other with respect to an imaginary line between the two adjacent unit pixels, and also the drive transistors of the two unit pixels that are adjacent to each other are arranged symmetrical to each other with respect to the imaginary line.

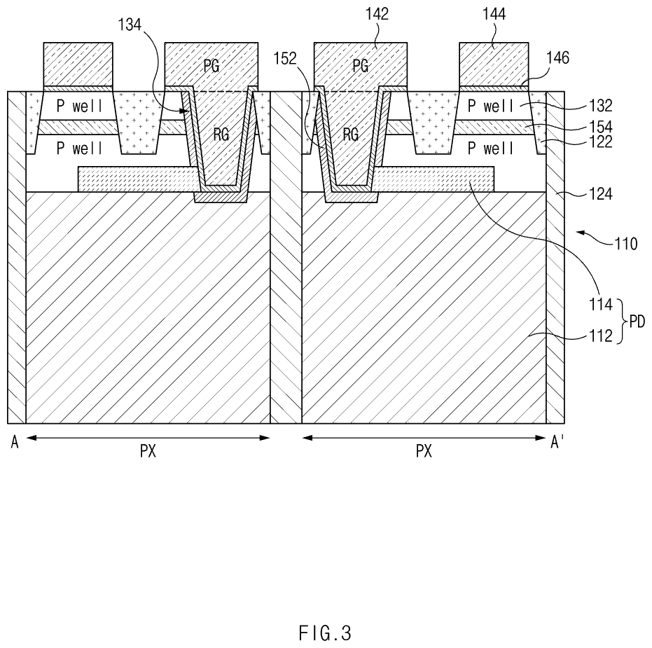

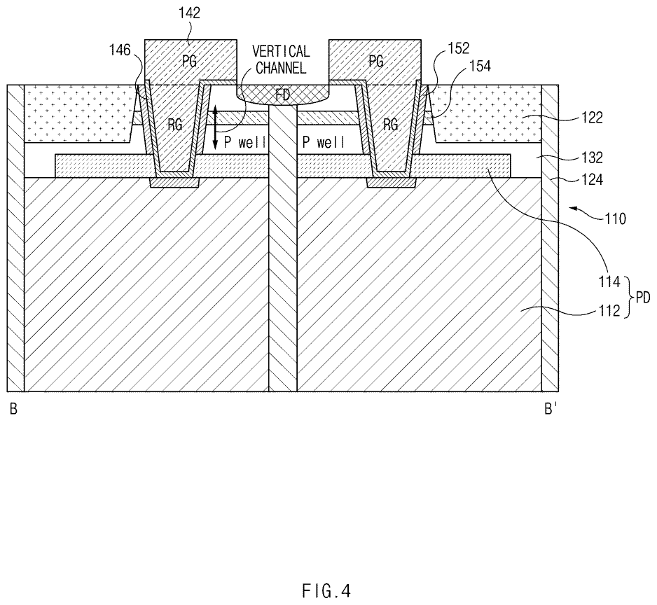

FIG. 3 is a cross-sectional view illustrating a cross-section of the pixel block taken along the line A-A′ shown in FIG. 2 based on some embodiments of the disclosed technology. FIG. 4 is a cross-sectional view illustrating a cross-section of the pixel block taken along the line B-B′ shown in FIG. 2 based on some embodiments of the disclosed technology.

Referring to FIGS. 3 and 4, a semiconductor substrate 110 may include a first surface and a second surface facing or opposite to the first surface, and may be isolated for each unit pixel (PX) by a pixel isolation structure 124. In the example, the first surface may be a surface upon which light is incident, and the second surface may be a surface in which transistors are formed. The semiconductor substrate 110 may be in a monocrystalline state, and may include a silicon-containing material.

The pixel isolation structure 124 may be disposed between adjacent photoelectric conversion regions (PDs) within the semiconductor substrate 110 to separate the adjacent photoelectric conversion regions (PDs) from each other. The pixel isolation structure 124 may include, for example, a deep trench isolation (DTI) structure in which an insulation material and a conductive material are embedded in a trench formed by etching the semiconductor substrate 110, and may be formed so that some areas thereof can penetrate the semiconductor substrate 110. For example, the pixel isolation structure 124 may penetrate the semiconductor substrate 110 in a region surrounding the photoelectric conversion regions (PDs), and may extend from the first surface of the semiconductor substrate 110 to a bottom surface of the floating diffusion region (FD) without penetrating the substrate 110 in a region where the floating diffusion region (FD) is formed.

The photoelectric conversion region (PD) may include N-type impurities. The photoelectric conversion region (PD) may convert light incident through the first surface of the semiconductor substrate 110 to generate photocharges and accumulate the generated photocharges. The photoelectric conversion element PD may include, e.g., a photodiode, a photo transistor, a photo gate, or other photosensitive circuitry capable of converting light into a pixel signal (e.g., a charge, a voltage or a current). The photoelectric conversion regions (PDs) of adjacent unit pixels (PXs) may be isolated from each other by the pixel isolation structure 124. Each of the photoelectric conversion regions (PDs) may be formed to partially contact a side surface of the transfer gate 142. For example, the photoelectric conversion region (PD) may be formed such that a portion thereof extends higher than a bottom surface of the recess gate (RG) of the transfer gate 142 toward the second surface of the semiconductor substrate 110, and the extended portion of the photoelectric conversion region (PD) contacts some parts of lower side surfaces of the recess gate (RG). The photoelectric conversion region (PD) may include a first photoelectric conversion region 112 and a second photoelectric conversion region 114 disposed over the first photoelectric conversion region 112.

The first photoelectric conversion region 112 may extend toward the first surface of the semiconductor substrate 110 to be in contact with the first surface of the semiconductor substrate 110, and may extend toward the bottom surface of the transfer gate 142. For example, the first photoelectric conversion region 112 may be disposed below a well region 132 and the second photoelectric conversion region 114 such that the bottom surface of the first photoelectric conversion region 112 contacts the first surface of the semiconductor substrate 110 and the top surface of the first photoelectric conversion region 112 contacts the well region 132 and the second photoelectric conversion region 114. The first photoelectric conversion region 112 may be isolated from the recess gate (RG) by a passivation layer 152.

The second photoelectric conversion region 114 may be disposed on the first photoelectric conversion region 112 so as to contact the well region 132 and the first photoelectric conversion region 112. For example, the second photoelectric conversion region 114 may be disposed such that the top surface thereof contacts the well region 132 and the bottom surface thereof contacts the first photoelectric conversion region 112. At this time, the second photoelectric conversion region 114 may be disposed on the first photoelectric conversion region 112 so as to partially cover the upper portion of the first photoelectric conversion region 112 rather than entirely covering the upper portion of the first photoelectric conversion region 112. For example, the second photoelectric conversion region 114 may be disposed on the first photoelectric conversion region 112 so as to contact a portion of the top surface of the first photoelectric conversion region 112. The second photoelectric conversion region 114 may have a different impurity concentration from that of the first photoelectric conversion region 112. Alternatively, the second photoelectric conversion region 114 may have the same impurity concentration as the first photoelectric conversion region 112.

In addition, the second photoelectric conversion region 114 may be disposed to be in contact with some of the lower side surfaces of the recess gate (RG). For example, when viewed in a plane as shown in FIG. 2, a side surface (e.g., a side surface adjacent to the pixel isolation structure 124) distant from the central portion of the photoelectric conversion region (PD) from among the side surfaces of the recess gate (RG) may be formed so as not to contact the second photoelectric conversion region 114. Among the side surfaces of the recess gate (RG), the remaining side surfaces of the recess gate (RG) other than the side surface contacting the second photoelectric conversion region 114 may contact the passivation layer 152. The second photoelectric conversion region 114 may be disposed below the bottom surface of the device isolation structure 122.

In this way, among the side surfaces of the recess gate (RG), some side surfaces located close to the central portion of the photoelectric conversion region (PD) are disposed to partially contact the second photoelectric conversion region 114, so that a distance (channel length) between the photoelectric conversion region and the floating diffusion region is shortened, resulting in an increase in transmission efficiency of photocharges.

A well region 132 that forms a PN junction with the photoelectric conversion region (PD) and forms a channel of transistors may be formed over the photoelectric conversion region (PD) in the semiconductor substrate 110. The well region 132 may include P-type impurities. The floating diffusion region (FD) may be formed in the well region 132.

In each unit pixel (PX), the active region where the drive transistor is formed and the recess gate (RG) may be isolated from each other by the device isolation structure 122. The device isolation structure 122 may include a shallow trench isolation (STI) structure. In a boundary region between the unit pixels (PX), the pixel isolation structure 124 may be formed to penetrate the device isolation structure 122.

The transfer gate 142 may selectively form a channel between the photoelectric conversion region (PD) and the floating diffusion region (FD) according to a transfer signal, so that the transfer gate 142 can transfer photocharges generated by the photoelectric conversion region (PD) to the floating diffusion region (FD). The transfer gate 142 may include a recess gate (RG) in which a portion of the recess gate (RG) is embedded in the semiconductor substrate 110. The recess gate (RG) may extend from the second surface of the semiconductor substrate 110 toward the first surface of the semiconductor substrate 110 so as to penetrate the well region 132 and the passivation layer 154. In addition, the transfer gate 142 may include a planar gate (PG) connected to the recess gate (RG).

Each of the transfer gate 142 and the drive gate 144 may include a gate electrode and a gate insulation layer 146 disposed between the gate electrode and the semiconductor substrate 110. In the present embodiment, a situation in which the second photoelectric conversion region 114 contacts the recess gate (RG) of the transfer gate 142 may refer to a situation in which the second photoelectric conversion region 114 contacts the gate insulation layer 146 of the recess gate (RG). The gate insulation layer 146 may include an oxide layer.

A passivation layer 152 may be formed in the semiconductor substrate 110 to cover the side surfaces and the bottom surface of a trench 134 in which the recess gate (RG) is formed. For example, the passivation layer 152 may be formed to cover the side surfaces and the bottom surface of the trench 134 except for a region of the trench 134 contacting the second photoelectric conversion region 114. For example, the passivation layer 152 may be formed along the side surfaces and the bottom surface of the trench 134 except the region of the trench 134 contacting the second photoelectric conversion region.

A passivation region 154 may be formed to extend below the floating diffusion region (FD) and the drive transistor in a horizontal direction. For example, the passivation region 154 may extend horizontally and be formed to cross the entire well region 132 in the horizontal direction at a height located below the floating diffusion region (FD) within the well region 132. As a result, the well region 132 may be divided into an upper well region and a lower well region by the passivation region 154.

In the image sensing device in which the recess gate (RG) is formed in a trench 134 formed by etching the semiconductor substrate 110 to a deep depth within each unit pixel (PX), dangling bonds may occur at an interface (side surfaces and a bottom surface) of the trench 134, thereby generating excess charges (excess electrons) as dark sources. Such excess charges may cause dark current and hot pixels, thereby deteriorating the operating characteristics of the image sensing device.

In the present embodiment, while a portion of the side surface of the trench is in contact with the second photoelectric conversion region 114, the remaining portions of the trench except the portion in contact with the second photoelectric conversion region 114 are covered by the passivation layer 152. The passivation layer 152 is formed in a region except for some regions contacting the second photoelectric conversion region 114 at the interface of the trench 134 in which the recess gate (RG) is formed, thereby reducing the number of excess charges at the interface of the trench 134.

In addition, since the passivation layer 154 is formed below the floating diffusion region (FD) and below the drive transistor within the well region 132, it is possible to prevent excess charges from flowing into the floating diffusion region (FD) or from affecting the operation of the drive transistor. The passivation layer 154 may reduce influence caused by excess charges generated at the interface of the trench in which the device isolation structure 122 is formed.

The passivation layers (152, 154) may include P-type impurities having a higher concentration than the well region 132. The impurity concentrations of the passivation layers (152, 154) may be formed to be the same or different from each other. The passivation layers (152, 154) may be formed to be connected to each other, and may be formed to have different thicknesses.

The floating diffusion region (FD) may be disposed within the well region 132 so as to contact the second surface of the semiconductor substrate 110. The floating diffusion region (FD) may include N-type impurities.

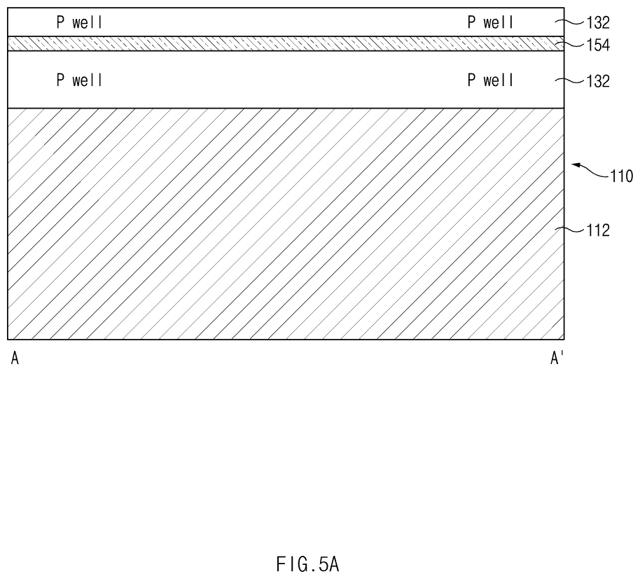

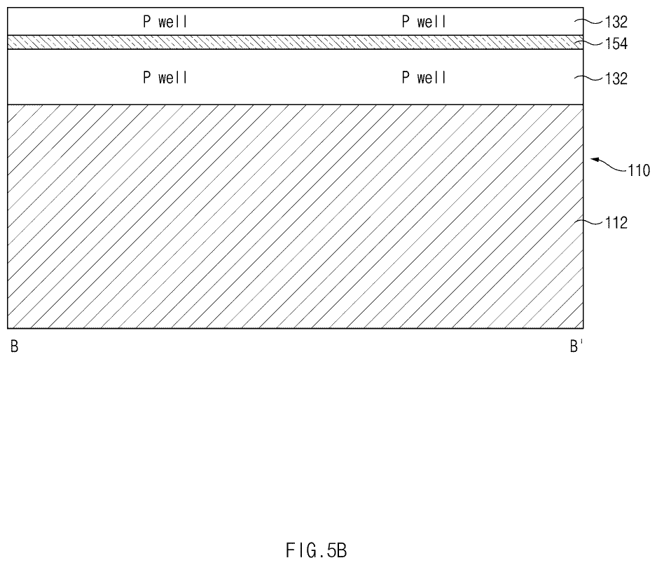

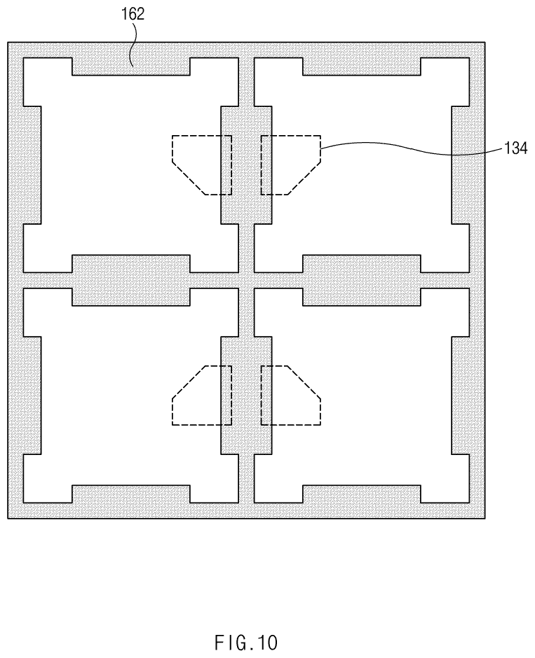

FIGS. 5A, 6A, 7A, 8A and 9A are cross-sectional views illustrating example methods of forming the structure shown in FIG. 3. FIGS. 5B, 6B, 7B, 8B and 9B are cross-sectional views illustrating example methods of forming the structure shown in FIG. 4. FIG. 10 is a plan view illustrating an example of a mask pattern for forming a second photoelectric conversion region.

Referring to FIGS. 5A and 5B, a first photoelectric conversion region 112 may be formed by implanting N-type impurities into the semiconductor substrate 110 including P-type impurities. A region in which P-type impurities remain on the first photoelectric conversion region 112 in the semiconductor substrate 110 may be used as the well region 132.

Subsequently, the passivation layer 154 may be formed by implanting P-type impurities at a predetermined depth within the well region 132. The passivation layer 154 may be or include a region doped with P-type impurities at a higher concentration than the well region 132. The passivation layer 154 may be formed in a horizontal direction with respect to the entire well region 132. For example, the well region 132 may be divided into an upper region and a lower region by the passivation layer 154.

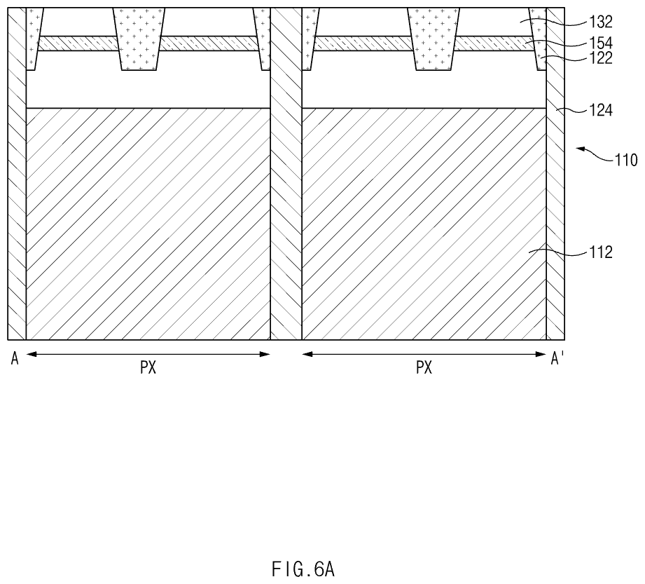

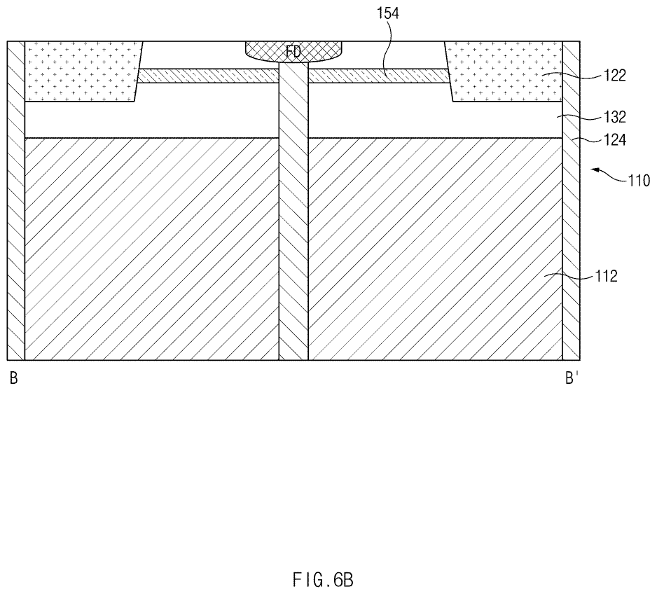

Referring to FIGS. 6A and 6B, a floating diffusion region (FD) may be formed in the well region 132 to be located at the center of each pixel block. For example, a floating diffusion region (FD) may be formed by implanting N-type impurities to a predetermined depth from the second surface of the semiconductor substrate 110 at the center of each pixel block including four unit pixels adjacent to each other.

Subsequently, a device isolation structure 122 may be formed in the well region 132 including the passivation layer 154, and a pixel isolation structure 124 may be formed in a boundary region of the unit pixels (PXs).

The device isolation structure 122 may define an active region where transistors are formed in each unit pixel (PX). The device isolation structure 122 may include an STI structure, and may be formed to penetrate the passivation layer 154.

The pixel isolation structure 124 may isolate photoelectric conversion regions 112 of adjacent unit pixels (PX) from each other. The pixel isolation structure 124 may include a DTI structure. The pixel isolation structure 124 may be formed so as not to penetrate the semiconductor substrate 110 in a region where the floating diffusion region (FD) is formed, and may be formed to penetrate the semiconductor substrate 110 in other regions.

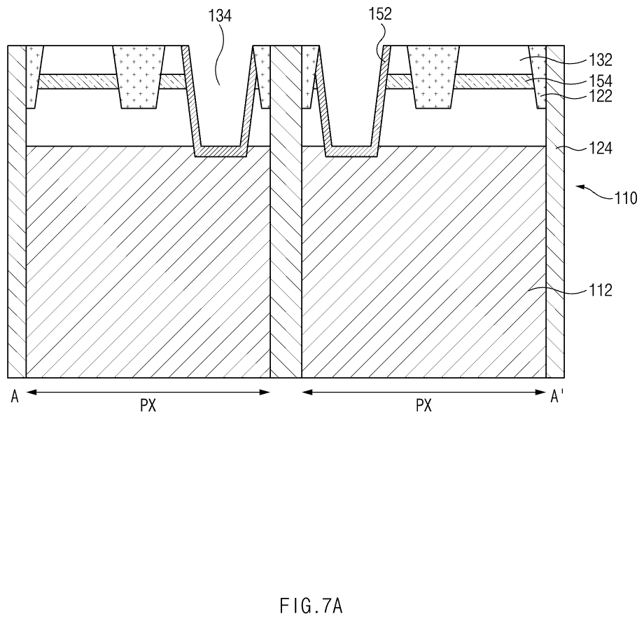

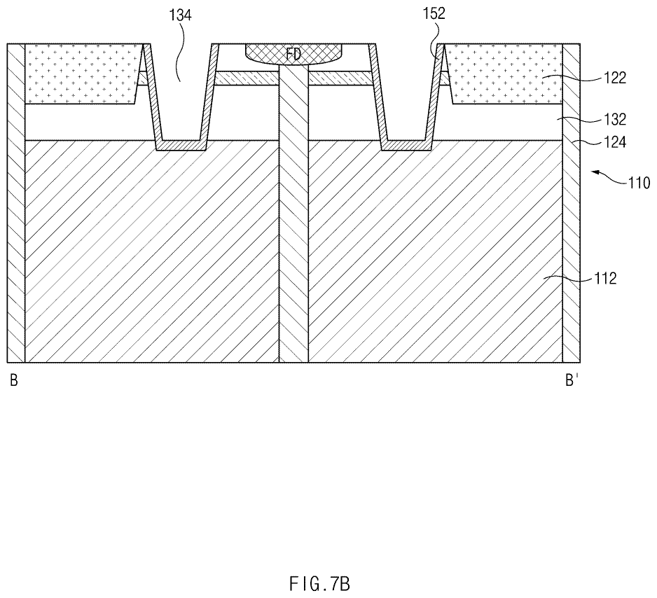

Referring to FIGS. 7A and 7B, a region in which the recess gate (RG) is to be formed in the semiconductor substrate 110 may be etched to a predetermined depth to form a trench 134. For example, the well region 132 and the passivation layer 154 of a region in which the recess gate (RG) is to be formed may be etched to expose the first photoelectric conversion region 112, resulting in formation of the trench 134.

Thereafter, a mask pattern (not shown) may be formed on the semiconductor substrate 110 to open the trench 134 and cover other regions. Subsequently, P-type impurities may be implanted into the trench 134, thereby forming a passivation layer 152 within the semiconductor substrate 110 that is in contact with sidewalls and bottom surface of the trench 134. For example, the passivation layer 152 may be formed by implanting impurities into the trench 134 through a plasma doping (PLAD) process.

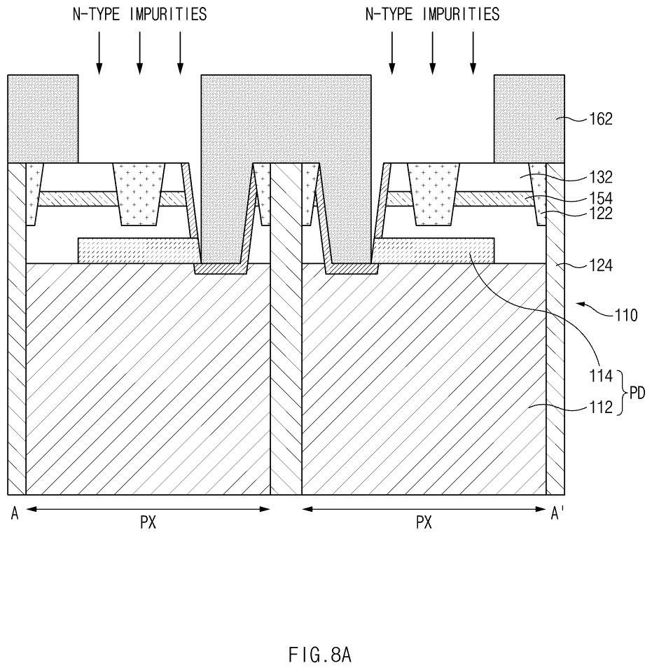

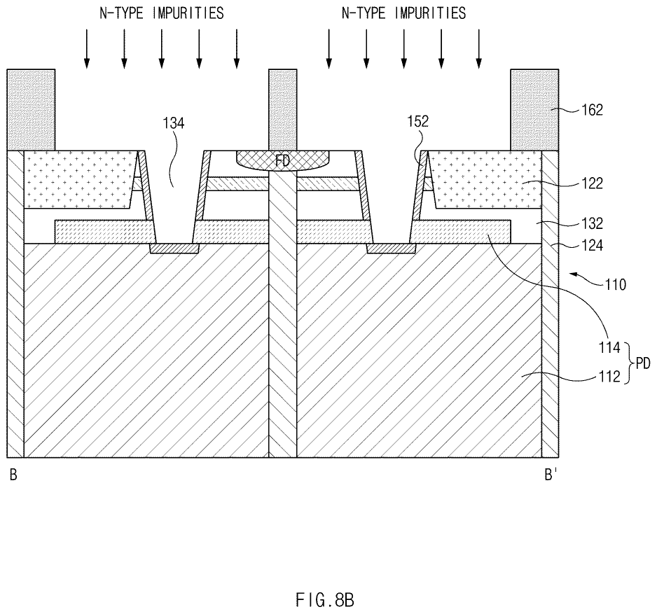

Referring to FIGS. 8A, 8B, and 10, a photoresist layer may be formed on the second surface of the semiconductor substrate 110 and then patterned to form a mask pattern 162 that covers the pixel isolation structure 124 and a portion of the trench 134 (e.g., a region adjacent to the pixel isolation structure 124 in the trench 134).

As shown in FIG. 10, the mask pattern 162 may have a shape in which the central portions of four sides of regions defining unit pixel regions protrude inward of the unit pixel regions. Thus, the unit pixel regions of the mask pattern 162 have protruding portions disposed at the four sides. At this time, some portions of the protruding regions may cover a portion of the trench 134, and remaining portions of the protruding regions may be used as a dummy region. For example, in order to prevent the shape of the mask pattern 162 from being distorted during a process of forming the mask pattern 162, the mask pattern 162 may be formed to be symmetrical in the row direction and the column direction.

Subsequently, by using the mask pattern 162 as an ion implantation mask, N-type impurities may be implanted into the semiconductor substrate 110 through the second surface of the semiconductor substrate 110, resulting in formation of a second photoelectric conversion region 114. At this time, by adjusting ion implantation energy, the second photoelectric conversion region 114 may be formed on the first photoelectric conversion region 112 so as to partially contact the top surface of the first photoelectric conversion region 112 within the well region 132. In addition, N-type impurities are implanted into a portion of the passivation layer 152 so that the implanted portion is converted into the second photoelectric conversion region 114 having the N-type impurities. As a result, the second photoelectric conversion region 114 may be formed to contact a portion of the side surfaces of the trench 134. For example, the second photoelectric conversion region 114 may be introduced into the passivation layer 152, and may thus contact a portion of the side surfaces of the trench 134.

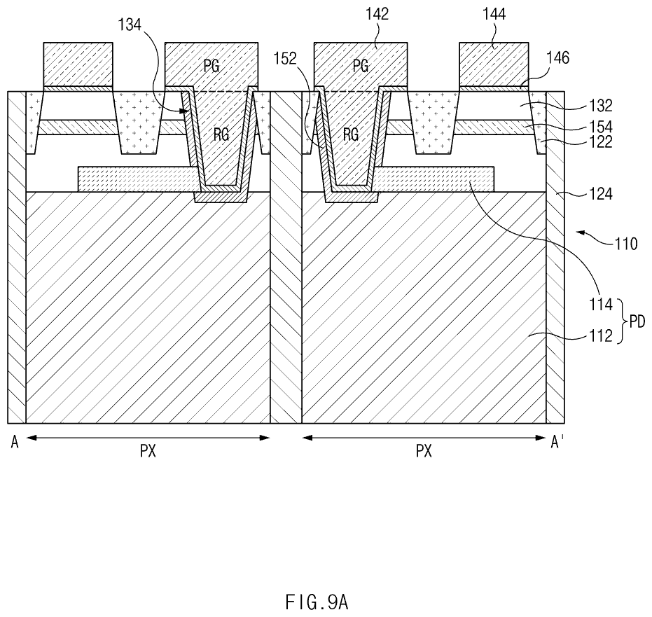

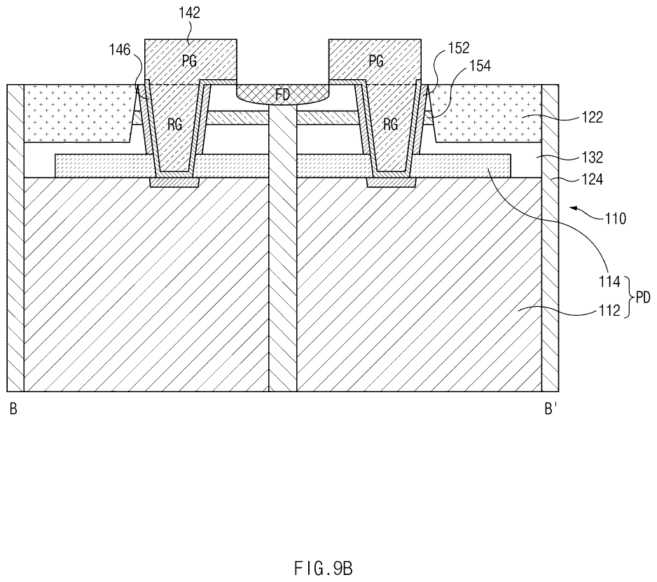

Referring to FIGS. 9A and 9B, a transfer gate 142 and a drive gate 144 may be formed not only within the trench 134, but also on the second surface of the semiconductor substrate 110. For example, an insulation layer may be formed not only on the side surface and bottom surface of the trench 134, but also on the second surface of the semiconductor substrate 110, and a gate electrode material may be formed on the insulation layer so as to fill the trench 134. At this time, the insulation layer may include an oxide layer, and the gate electrode material may include polysilicon.

Thereafter, the gate electrode material and the insulation layer are patterned to form the transfer gate 142 and the drive gate 144 including a gate insulation layer 146.

The transfer gate 142 may include a recess gate (RG) embedded or disposed in a semiconductor substrate 110 and a planar gate (PG) formed on the second surface of the semiconductor substrate 110 while contacting the recess gate (RG). At this time, the side surface of the recess gate (RG) may partially contact the second photoelectric conversion region 114.

As is apparent from the above description, the image sensing device according to the embodiments of the disclosed technology may improve operation characteristics thereof.

The image sensing device according to the embodiments of the disclosed technology may increase transmission efficiency of a transfer transistor.

In addition, the image sensing device according to the embodiments of the disclosed technology may reduce the degree of influence caused by dark sources.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a semiconductor substrate;
a well region in the semiconductor substrate and including first-type impurities;
a photoelectric conversion region disposed below the well region to be in contact with the well region and including second-type impurities opposite to the first-type impurities, the photoelectric conversion region configured to generate photocharges in response to light incident on the photoelectric conversion region;
a transfer gate including a recess gate embedded in the semiconductor substrate and configured to transfer the photocharges; and
a first passivation layer disposed to cover at least one side surface and a bottom surface of the recess gate within the semiconductor substrate,
wherein
a portion of the photoelectric conversion region is in contact with the at least one side surface of the recess gate.

2. The image sensing device according to claim 1, wherein the photoelectric conversion region includes:
a first photoelectric conversion region having a top surface that partially contacts the well region and being isolated from the recess gate by the first passivation layer; and
a second photoelectric conversion region disposed over the first photoelectric conversion region to contact the top surface of the first photoelectric conversion region, the second photoelectric conversion region being in contact with the at least one side surface of the recess gate.

3. The image sensing device according to claim 2, wherein:
the second photoelectric conversion region has a different impurity concentration from an impurity concentration of the first photoelectric conversion region.

4. The image sensing device according to claim 2, wherein the first photoelectric conversion region has a bottom surface being in contact with a first surface of the semiconductor substrate.

5. The image sensing device according to claim 1, wherein the recess gate includes:
a gate electrode; and
a gate insulation layer disposed between the gate electrode and the semiconductor substrate.

6. The image sensing device according to claim 1, wherein:
the first passivation layer includes the first-type impurities.

7. The image sensing device according to claim 6, wherein:
the first passivation layer has a higher impurity concentration than the well region.

8. The image sensing device according to claim 1, further comprising:
a second passivation layer including the first-type impurities and extending horizontally within the well region.

9. The image sensing device according to claim 8, wherein:
the second passivation layer is formed to extend below a floating diffusion region.

10. The image sensing device according to claim 8, wherein:
the second passivation layer is formed to entirely cross the well region in a horizontal direction.

11. The image sensing device according to claim 8, wherein:
the second passivation layer has a higher impurity concentration than the well region.

12. An image sensing device comprising:
a plurality of unit pixels disposed adjacent to each other; and
a floating diffusion region disposed between the plurality of unit pixels and shared by the plurality of unit pixels to receive photocharge from the plurality of unit pixels,
wherein each of the plurality of unit pixels includes:
a semiconductor substrate;
a photoelectric conversion region disposed in the semiconductor substrate that converts incident light into photocharge;
a well region disposed on the photoelectric conversion region and being in contact with the photoelectric conversion region within the semiconductor substrate;
a recess gate disposed in the semiconductor substrate and having a first side surface being in contact with the photoelectric conversion region and a second side surface opposite to the first side surface; and
a first passivation layer covering the second side surface and a bottom surface of the recess gate within the semiconductor substrate.

13. The image sensing device according to claim 12, wherein the photoelectric conversion region includes:
a first photoelectric conversion region having a top surface that partially contacts the well region and being isolated from the recess gate by the first passivation layer; and
a second photoelectric conversion region disposed on the first photoelectric conversion region to contact the top surface of the first photoelectric conversion region, the second photoelectric conversion region being in contact with at least one side surface of the recess gate.

14. The image sensing device according to claim 13, wherein:
the second photoelectric conversion region has a different impurity concentration from an impurity concentration of the first photoelectric conversion region.

15. The image sensing device according to claim 13, wherein the first photoelectric conversion region has a bottom surface being in contact with a first surface of the semiconductor substrate.

16. The image sensing device according to claim 12, wherein the first passivation layer includes:
an impurity region having impurities with a same type as the well region at a higher impurity concentration than the well region.

17. The image sensing device according to claim 12, further comprising:
a second passivation layer disposed to extend horizontally within the well region.

18. The image sensing device according to claim 17, wherein:
the second passivation layer is disposed to extend below the floating diffusion region.

19. A method for manufacturing an image sensing device comprising:
forming a first photoelectric conversion region in a semiconductor substrate including impurities of a first type by implanting impurities of a second type opposite to the first type;
forming a trench by etching the semiconductor substrate;
forming a passivation layer on sidewalls and a bottom surface of the trench by implanting the impurities of the first type into the trench;
forming a mask pattern covering a portion of the trench on the semiconductor substrate;
forming a second photoelectric conversion region contacting a portion of side surfaces of the trench by implanting the impurities of the second type into the semiconductor substrate using the mask pattern as an ion implantation mask; and
forming a transfer gate to fill the trench.

20. The method according to claim 19, wherein:
in forming the mask pattern, shaping the mask pattern to have a shape in which central portions of four sides of a region defining a unit pixel region protrude inward of the unit pixel region.
